(19) United States
(12) Patent Application Publication
(10) Pub. No.: US 2012/0305882 A1
(43) Pub. Date: Dec. 6, 2012

(54) NiO-based Resistive Random Access Memory and the Preparation Method Thereof

(75) Inventors: Jingjing Gu, Shanghai (CN); Qingqing Sun, Shanghai (CN); Pengfei Wang, Shanghai (CN); Peng Zhou, Shanghai (CN); Wei Zhang, Shanghai (CN)

(73) Assignee: Fudan University, Shanghai (CN)

(21) Appl. No.: 13/498,973

(22) PCT Filed: Sep. 23, 2011
(86) PCT No.: PCT/CN11/01610

§ 371 Date: Mar. 29, 2012

(30) Foreign Application Priority Data
Oct. 15, 2010 (CN) 201010508181.0

(51) Int. Cl. H01L 45/00; H01L 21/02

(52) U.S. Cl. 257/4; 438/382; 257/E45.003; 257/E21.004

(57) ABSTRACT

The present invention belongs to the technical field of memory storage and specially relates to a NiO-based resistive random access memory system (RRAM) and a preparation method thereof. The RRAM is comprised of a substrate and a metal-insulator-metal (MIM) structure, wherein the electrodes are metal films, such as copper, aluminum, etc., capable of being applied to the interconnection process, and the resistive switching insulator is an Al₂O₃/NiO/Al₂O₃ laminated dielectric film. The MIM structure in the invention shows stable switching between the bi-stable resistance states as well as memory features; compared with the RRAM that only uses a single NiO-based dielectric film, the storage window is increased, and the resistance stability is improved. Therefore, the NiO-based RRAM has a good prospect in actual application. The present invention further provides a method for preparing the abovementioned memory storage system.

### TECHNICAL FIELD

This invention belongs to the technical field of memory storage and specially relates to a NiO-based resistive random access memory and the preparation method thereof.

### BACKGROUND TECHNOLOGY

1. Nonvolatile memory has become the focus of the technical field of the current information storage technology. With the continuing decrease of the characteristic dimensions of the semiconductor devices, the quantity of the charges stored in the traditional floating gate transistor memory declines, the write-in voltage is difficult to drop and the reliability also gets poor, so the development of novel nonvolatile memory storage becomes very important.

In recent years, the study of resistive random access memory system (RRAM) based on the variation of material resistance has become the focus. The RRAM's working principle is that, due to property change of the materials, memory has different resistant states and therefore stores data. FIG. 1 is an equivalent circuit diagram of an RRAM in the prior art. As shown in FIG. 1, the memory device consists of a transistor 13 and a memory unit 14, which are connected in series between a bit line 15 and a source potential 12; a word line 11 is used for switching control over the transistor 313. When accessing the data stored in the memory unit 14, the word line 11 applies a voltage onto the transistor 313 and opens the transistor 13, and the bit line 15 applies a voltage to the memory 14 to make a read current pass through the memory unit 14 and the transistor 13. Based on the output current, the data stored in the memory unit 14 can be read.

The basic memory unit of the RRAM is comprised of a metal-insulator-metal (MIM) structured resistor. The common resistive material has high-resistance state and a low-resistance state. FIG. 2 is a sectional view of a typical RRAM. The bottom electrode 108 and top electrode 106 of the RRAM usually adopt metal materials with stable chemical properties, such as Pt, Ti, etc., and the resistive-switching materials between the bottom electrode 108 and the top electrode 106 are usually binary or ternary metal oxides, such as TiO₂, ZrO, Cu₂O, SrTiO₃, etc. Like the storage principle of current major semiconductor memory storage, the RRAM does not depend on the quantity of charges stored in the capacitance structure to store information but depends on the resistivity variation of the materials to store the information. The resistivity of the materials is unrelated to the dimensions of the materials, so, theoretically, the storage performance of the RRAM does not decline with the shrinkage of the devices' dimensions. This determines that the potential integration capability of the RRAM is far higher than that of current major Flash floating gate memory storage. Furthermore, the RRAM device is simple in structure and is capable of easily realizing integration with the existing CMOS production process.

Among the variety of materials with resistive switching features, RRAM devices made from the NiO material are a hotspot of study because of advantages like simple components. The large-scaled industrial application of NiO-based RRAM has also been gradually realized. However, for mass production, more requirements on the properties are necessary, such as the resistance window, the stability and persistency of the resistance switching, etc., of the NiO-based RRAM in the industrial field, and the methods for strengthening the properties of the NiO-based RRAM attract academic and industrial attention.

### DESCRIPTION OF THIS DISCLOSURE

The present invention aims to provide a NiO-based resistive random access memory system (RRAM) and a preparation method thereof.

The RRAM disclosed in the present invention has a metal-insulator-metal (MIM) structure, wherein the metals form metal films as top and bottom electrodes and the insulator layer has an Al₂O₃/NiO/Al₂O₃ laminated structure.

The top and bottom electrodes are made of copper, aluminum, gold, titanium, titanium nitride or tantalum nitride.

In the Al₂O₃/NiO/Al₂O₃ laminated structure, the Al₂O₃ layer is prepared by atomic layer deposition (ALD), while the NiO layer is prepared by physical vapor deposition (PVD) or atomic layer deposition.

The thickness of the dielectric film is 20-60 mm and can be controlled by the PVD time and the ALD period.

The preparation method of the RRAM with the MIM structure is as follows:

1) grow a SiO₂ dielectric layer on a Si substrate by thermal oxidation or chemical vapor deposition, to reduce the parasitic effect and prevent Si and the bottom electrode from forming an alloy;

2) prepare the bottom electrode by electroplating, steaming or sputtering;

3) prepare the Al₂O₃ electric layer material in the Al₂O₃/NiO/Al₂O₃ laminated structure by ALD;

4) prepare the NiO electric layer material in the Al₂O₃/NiO/Al₂O₃ laminated structure by PVD or ALD;

5) prepare the Al₂O₃ electric layer material in the Al₂O₃/NiO/Al₂O₃ laminated structure by ALD;

6) use a hard mask to prepare a metal film that is used as the top electrode and the contact patterns by PVD.

The present invention has the following advantages:

First, switching between bi-stable resistance states is stable under the condition of continuous scanning drive of the DC voltage. Compared with RRAM that uses a single NiO-based dielectric layer as the insulator layer, the improved NiO-based RRAM having the Al₂O₃/NiO/Al₂O₃ laminated structure is characterized by a bi-stable resistance state and stable resistance in rewriting operations that are carried out continuously; the voltage difference of the switching between the bi-stable resistance states is also stabilized about 1V, so rewriting failure caused by overlapping of the switching scopes of the state switching voltages in the low-voltage operation of the unipolar RRAM under a single voltage polarity can be effectively avoided, and the stability and reliability of the traditional NiO-based RRAM are effectively improved.

Second, for the NiO-based RRAM having the Al₂O₃/NiO/Al₂O₃ laminated structure, and under the condition that the limited current is 5 mA at the low-resistance state, the resistance window of the bi-stable resistance state reaches 10³, the voltage difference of switching from the high-resistance state to the low-resistance state is about 1.7 V, that from the low-resistance state to the high-resistance state is about 0.5V and the maximal current of the high-resistance state is about 15 mA. Those properties show that the present invention has a great application prospect in the field of novel, low-consumption, nonvolatile memory storage systems.

### BRIEF DESCRIPTION OF THE ATTACHED DRAWINGS

FIG. 1 is an equivalent circuit diagram of a phase-change memory system in the prior art.

FIG. 2 is a sectional view of a typical RRAM unit with a single resistive switching material layer.

FIG. 3a illustrates the current-voltage features of the RRAM of this invention, and FIG. 3b illustrates the current-voltage features of an RRAM that uses a single NiO-based dielectric layer as the insulator layer.

FIG. 4 is a structural view of the memory unit of the RRAM of this invention.

FIG. 5 illustrates the multiple rewriting features of the RRAM of this invention in comparison with an RRAM that uses a single NiO-based dielectric layer as the insulator layer.

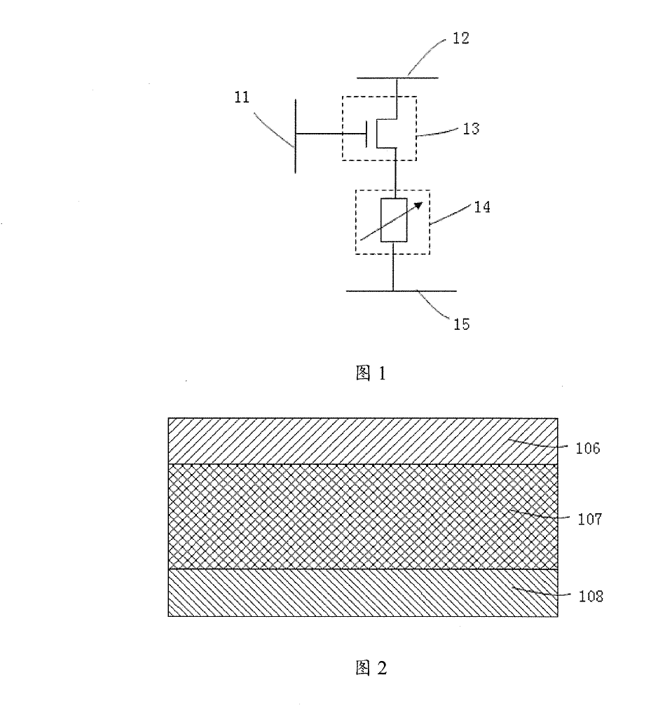

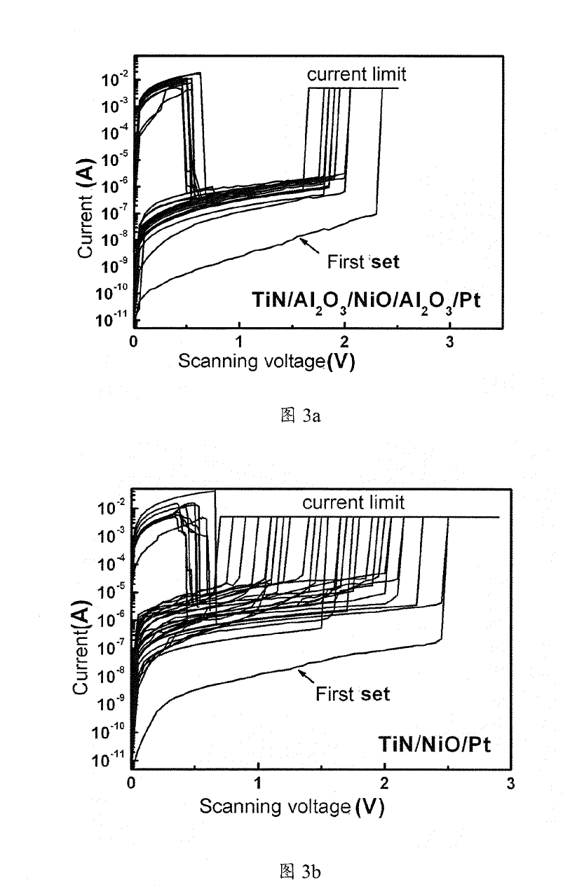

### OPTIMAL EMBODIMENT OF THIS INVENTION

This invention is further described in detail by combining the attached drawings and the embodiment.

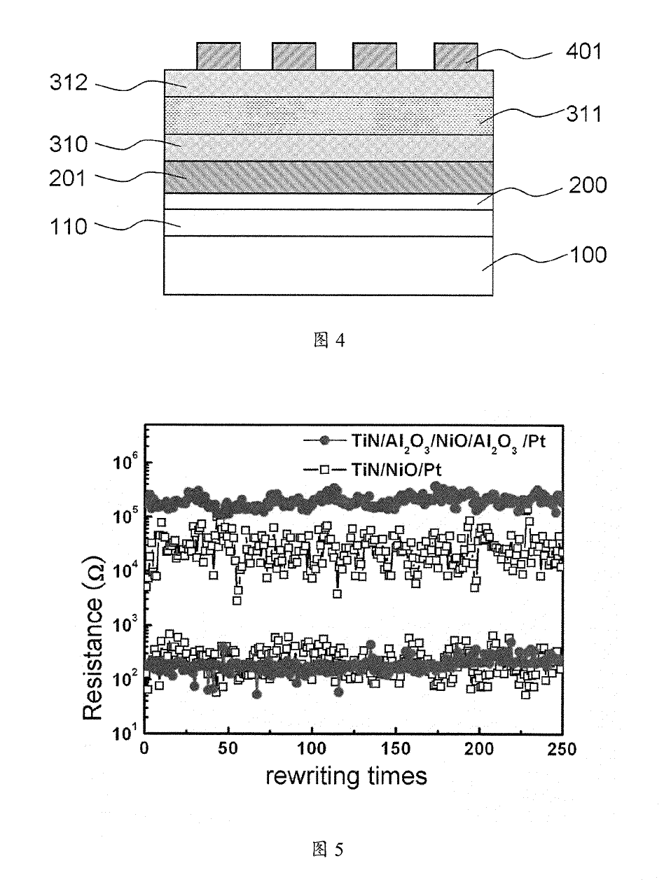

Grow a dielectric silica layer 110, used as a substrate, on a monocrystalline silicon layer 100 by thermal oxidation or chemical vapor deposition, wherein the oxidation temperature is 1,100□, the oxidation time is 10 min, and the silica layer is 100 nm-1,000 nm thick. Prepare the metal film 201 of a bottom electrode by sputtering growth (in this embodiment, Pt is used). Grow a Ti metal film 200 as the adhesive layer of the metal film of the bottom electrode between the metal film 200 of the bottom electrode and the silica dielectric layer 110. Prepare a first Al₂O₃ film 310 with a thickness of 2-6 nm on the metal film 200 of the bottom electrode by atomic layer deposition (ALD). Prepare a NiO film 311 with a thickness of 20-50 nm on the first Al₂O₃ film 310 by physical vapor deposition (PVD) or atomic layer deposition (ALD) (in this embodiment, the PVD is adopted). Prepare a second Al₂O₃ film 312 with a thickness of 2-6 nm on the NiO film by atomic layer deposition (ALD). On the second Al₂O₃ film 312, prepare the upper electrode's film (in this embodiment, TiN film is adopted) by PVD and use a hard mask to form contact patterns which are spots with diameters of 100 nm-400 nm. As shown in FIG. 4.

FIG. 3a illustrates the current-voltage features of the RRAM; as a reference, FIG. 3b illustrates the current-voltage features of an RRAM that uses a single NiO-based dielectric layer as the insulator layer. The scanning bias voltage is applied onto the test probes of the top electrode and the bottom electrode. See FIG. 3a for the test results of the current-voltage features. When the voltage is switched from 0V, the RRAM shows the high-resistance feature, and when the voltage is higher than 1.5V, the RRAM is suddenly switched into low-resistance state; at that time a limited current (5 mA in this embodiment) is required so as to avoid damaging the RRAM due to too large a current. When the voltage is switched from 0V to 0.5V, the current of the RRAM suddenly changes again, the resistance state is switched from the low-resistance state to the high-resistance state, the repeated times are the same and the voltage differences generated by switching between the high-resistance and low-resistance states are stable. FIG. 5 illustrates the resistance change of the RRAM in this embodiment and that of an RRAM that is prepared by the same process and uses the single NiO-based dielectric layer as the insulator during 200 repeated rewriting operations. It can be seen that the RRAM in this embodiment shows high resistance stability in the repeated rewriting operations.

The abovementioned embodiment is an example of this invention only. Although the disclosure of the optimal embodiment and attached drawings of the present invention is intended for description, skilled persons in this field would be capable of understanding that, within the spirit and scope claimed by the present invention, any replacement, variation or modification is possible. Therefore, the present invention shall not be limited by the contents disclosed in the optimal embodiment and the attached drawings.

### INDUSTRIAL APPLICATION

The NiO-based RRAM of the present invention shows stable switching between the bi-stable resistance states under the condition of a continuous scanning drive of the DC voltage. Compared with an RRAM that uses a single NiO-based dielectric layer as the insulator layer, the improved NiO-based RRAM having the Al₂O₃/NiO/Al₂O₃ laminated structure is characterized by a bi-stable resistance state and stable resistance in the rewriting operations that are carried out continuously; the voltage difference of the switching between the bi-stable resistance states is also stabilized at about 1V, so rewriting failures caused by overlapping of the switching scopes of the state switching voltages in the low-voltage operation of the unipolar resistive memory under a single voltage polarity can be effectively avoided. Furthermore, the stability and reliability of traditional NiO-based RRAM are effectively improved.

The NiO-based RRAM of the present invention has the Al₂O₃/NiO/Al₂O₃laminated structure, so under the condition that the limited current is 5 mA at the low-resistance state, the ratio of high/low resistances of the bi-stable resistance states reaches 10³, the voltage difference generated by switching from the high-resistance state to the low-resistance state is about 1.7V, that from the low-resistance state to the high-resistance state is about 0.5V and the maximal current of the high-resistance state is about 15 mA. These properties show that the present invention has a great application prospect in the field of novel, low-consumption, nonvolatile memory storage systems.

1. A NiO-based resistive random access memory characterized in that, comprising a metal-insulator-metal structure, wherein the metals form metal films as top and bottom electrodes and the insulator layer has an Al₂O₃/NiO/Al₂O₃ laminated structure.

2. The resistive random access memory of claim 1, wherein the top and bottom electrodes are made of copper, aluminum, gold, titanium, titanium nitride or tantalum nitride.

3. The resistive random access memory of claim 1, in the Al₂O₃/NiO/Al₂O₃ laminated structure, the Al₂O₃ layer is prepared by atomic layer deposition, while the NiO layer is prepared by physical vapor deposition or atomic layer deposition.

4. The preparation method of the resistive random access memory of claim 1 is as follows:
1) grow a SiO₂ dielectric layer on a Si substrate by thermal oxidation or chemical vapor deposition, to reduce the parasitic effect and prevent Si and the bottom electrode from forming an alloy;
2) prepare the bottom electrode by electroplating, steaming or sputtering;
3) prepare the Al₂O₃ electric layer material in the Al₂O₃/NiO/Al₂O₃ laminated structure by atomic layer deposition;
4) prepare the NiO electric layer material in the Al₂O₃/NiO/Al₂O₃ laminated structure by physical vapor deposition or atomic layer deposition;
5) prepare the Al₂O₃ electric layer material in the Al₂O₃/NiO/Al₂O₃ laminated structure by atomic layer deposition;
6) use a hard mask to prepare a metal film that is used as the top electrode and the contact patterns by physical vapor deposition.
